(19) United States
(12) Patent Application Publication
(10) Pub. No.: US 2011/0092036 A1
(43) Pub. Date: Apr. 21, 2011

(54) METHOD FOR MANUFACTURING SEMICONDUCTOR DEVICE

(75) Inventor: Yoshitaka NAKAMURA, Tokyo (JP)

(73) Assignee: ELPIDA MEMORY, INC., Tokyo (JP)

(21) Appl. No.: 12/857,607

(22) Filed: Aug. 17, 2010

(30) Foreign Application Priority Data
Oct. 15, 2009 (JP) 2009-238238

(51) Int. Cl. H01L 21/8242; H01L 21/02

(52) U.S. Cl. 438/253; 438/396; 257/E21.018; 257/E21.648

(57) ABSTRACT

After forming a first capacitor hole, first mask material is filled in an upper portion of the first capacitor hole. A second capacitor hole is formed so that it is aligned with the first capacitor hole. After removing the first mask material, a lower electrode is formed in the first and second capacitor holes by one film formation step. After that, a capacitor dielectric film and an upper electrode are sequentially formed on the lower electrode.

This application is based upon and claims the benefit of priority from Japanese Patent Application No. 2009-238238, filed on Oct. 15, 2009, the disclosure of which is incorporated herein in its entirety by reference.

### BACKGROUND OF THE INVENTION

1. Field of the Invention

The present invention relates to a method for manufacturing semiconductor device.

2. Description of the Related Art

Memory cells such as DRAM (Dynamic Random Access Memory) include transistors for selection and capacitors. As a micro-processing technique has been recently advanced, the memory cells have been also miniaturized. Regarding this, a structure has been examined which effectively keeps accumulated charges of the capacitors. As an example of the structure, a three-dimensional capacitor having a high aspect ratio has been adopted which is formed in a capacitor hole formed in a silicon oxide film.

As disclosed in JP-A. Nos. 2006-216649 and 2004-39683, as a method of forming capacitor holes having a high aspect ratio accompanied by the miniaturization, a technique has been developed in which the capacitor holes are formed in a depth direction in two times.

In the technique disclosed in JP-A No. 2006-216649, capacitors are formed by a following process.

(1) a plurality of first capacitor holes are formed in a first interlayer insulating film (silicon oxide film).

(2) a first conductive film (titanium nitride) is filled in the first capacitor holes and the conductive film outside the first capacitor holes is removed.

(3) a second interlayer insulating film (silicon oxide film) is formed.

(4) a plurality of second capacitor holes are formed in the second interlayer insulating film.

(5) a second conductive film (titanium nitride) is filled in the second capacitor holes and the conductive film outside the second capacitor holes is removed to form lower electrodes.

(6) a capacitor dielectric film and an upper electrode are sequentially formed on the lower electrodes.

In the technique disclosed in JP-A No. 2004-39683, capacitors are formed by a following process.

(1) a plurality of first capacitor holes are formed in a first interlayer insulating film (silicon oxide film).

(2) a SOG film is filled in the first capacitor holes and the SOG film outside the first capacitor holes is removed.

(3) a second interlayer insulating film (silicon oxide film) is formed.

(4) a plurality of second capacitor holes are formed in the second interlayer insulating film and then the SOG film is removed.

(5) a conductive film (titanium nitride) is filled in the first and second capacitor holes connected in a depth direction, thereby forming lower electrodes.

(5) a capacitor dielectric film and an upper electrode are sequentially formed on the lower electrodes.

As described above, in the techniques disclosed in JP-A Nos. 2006-216649 and 2004-39683, the capacitor holes having two steps are connected in a depth direction to obtain capacitors having a high aspect ratio.

### SUMMARY OF THE INVENTION

In one embodiment, there is provided a method for manufacturing a semiconductor device including a capacitor, the method comprising:

forming a first interlayer insulating film;

forming a first capacitor hole in the first interlayer insulating film;

filling a first mask material in an upper portion of the first capacitor hole;

forming a second interlayer insulating film on the first interlayer insulating film;

forming a second capacitor hole in the second interlayer insulating film so that the second capacitor hole is aligned with the first capacitor hole, the second capacitor hole being formed until the first mask material is exposed;

removing the first mask material;

forming a lower electrode in the first and second capacitor holes;

removing the first and second interlayer insulating films; and

sequentially forming a capacitor dielectric film and an upper electrode on an exposed surface of the lower electrode.

In another embodiment, there is provided a method for manufacturing a semiconductor device including a capacitor, the method comprising:

forming a first interlayer insulating film;

forming a first capacitor hole in the first interlayer insulating film;

filling a first mask material in an upper portion of the first capacitor hole;

forming a second interlayer insulating film on the first interlayer insulating film;

forming a second capacitor hole in the second interlayer insulating film so that the second capacitor hole is aligned with the first capacitor hole, the second capacitor hole being formed until the first mask material is exposed;

removing the first mask material;

forming a lower electrode having a pillar shape so that the lower electrode is filled in the first and second capacitor holes;

removing the first and second interlayer insulating films; and

sequentially forming a capacitor dielectric film and an upper electrode on an exposed surface of the lower electrode having the pillar shape.

In another embodiment, there is provided a method for manufacturing a semiconductor device including a capacitor, the method comprising:

forming a first interlayer insulating film;

forming a first capacitor hole in the first interlayer insulating film;

filling a first mask material in an upper portion of the first capacitor hole;

forming a second interlayer insulating film on the first interlayer insulating film;

forming a second capacitor hole in the second interlayer insulating film so that the second capacitor hole is aligned with the first capacitor hole, the second capacitor hole being formed until the first mask material is exposed;

removing the first mask material;

forming a lower electrode having a recess shape on inner walls of the first and second capacitor holes;

removing the first and second interlayer insulating films; and

sequentially forming a capacitor dielectric film and an upper electrode on an exposed surface of the lower electrode.

### BRIEF DESCRIPTIONS OF THE DRAWINGS

The above features and advantages of the present invention will be more apparent from the following description of certain preferred embodiments taken in conjunction with the accompanying drawings, in which:

FIGS. 1 to 9 are longitudinal sectional views showing a step of a method for manufacturing a semiconductor device according to a first exemplary embodiment.

FIG. 10 is a sectional view taken along a line A-A′ of the semiconductor device shown in FIG. 9.

FIGS. 11, 12, 14, 16, 18 and 20 are longitudinal sectional views showing a step of a method for manufacturing a semiconductor device according to a second exemplary embodiment.

FIG. 13 is a plan view of the semiconductor device shown in FIG. 12.

FIG. 15 is a plan view of the semiconductor device shown in FIG. 14.

FIG. 17 is a plan view of the semiconductor device shown in FIG. 16.

FIG. 19 is a plan view of the semiconductor device shown in FIG. 18.

FIGS. 21, 22, 24, 26, 28 and 30 are longitudinal sectional views showing a step of a method for manufacturing a semiconductor device according to a third exemplary embodiment.

FIG. 23 is a plan view of the semiconductor device shown in FIG. 22.

FIG. 25 is a plan view of the semiconductor device shown in FIG. 24.

FIG. 27 is a plan view of the semiconductor device shown in FIG. 26.

FIG. 29 is a plan view of the semiconductor device shown in FIG. 28.

FIG. 31 is a sectional view taken along a line A-A′ of the semiconductor device shown in FIG. 30.

In the drawings, reference numerals have the following meanings: 1: silicon substrate, 2: isolation insulating film, 3: gate insulating film, 4: gate electrode, 5, 6: diffusion layer region, 8: bit line, 9: active area, 11, 11a: polysilicon plug, 12: metal plug, 21, 22, 25: interlayer insulating film, 23: first interlayer insulating film, 24: second interlayer insulating film, 31: insulating film, 32: interlayer insulating film, 33: beam, 40: step, 41: step portion, 51: lower electrode, 52: capacitor dielectric film, 53: upper electrode, 81, 82: carbon film, 86: carbon film, 91: first capacity opening, 92: second capacity opening

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In addition, the exemplary embodiments below will be explained by dividing them into a plurality of sections or embodiments if necessary for convenience. They should not be construed as not being related to one another, and are in relations of modified embodiments of parts or the entirety thereof, detailed explanation, and supplemental explanations, etc., unless otherwise expressly described herein.

In a method for manufacturing a semiconductor device, a first interlayer insulating film including a first capacitor hole whose upper portion is filled with first mask material and a second interlayer insulating film including a second capacitor hole are sequentially formed. Then, the first mask material is removed. Thereby, the first capacitor hole and the second capacitor hole are made to communicate with each other, thereby constituting one capacitor hole. Then, a lower electrode is formed in the first and second capacitor holes communicating with each other by one process. Then, a capacitor dielectric film and an upper electrode are sequentially formed to cover surface of the lower electrode.

Like this, according to the method of the invention, since the first and second capacitor holes are formed in two times, it is possible to form the capacitor hole having a high aspect ratio. Since the first mask material is filled only in the upper portion of the first capacitor hole, it is possible to easily remove the first mask material in a subsequent process.

Since the lower electrode is formed in the capacitor hole by one film formation step, there is no concern that conductive resistance of the lower electrode is increased as a case where the lower electrode is formed in several stages. As a result, it is possible to provide a semiconductor device including capacitor in which lower electrode exhibits stable and low conductive resistance. In addition, yield and reliability of the semiconductor device are improved. Additionally, it is possible to reduce the manufacturing cost of the semiconductor device.

In the semiconductor device, the capacitor includes a step portion. As a result, contact areas between the capacitor dielectric film and the lower and upper electrodes are increased to improve the capacitor capacity.

### First Exemplary Embodiment

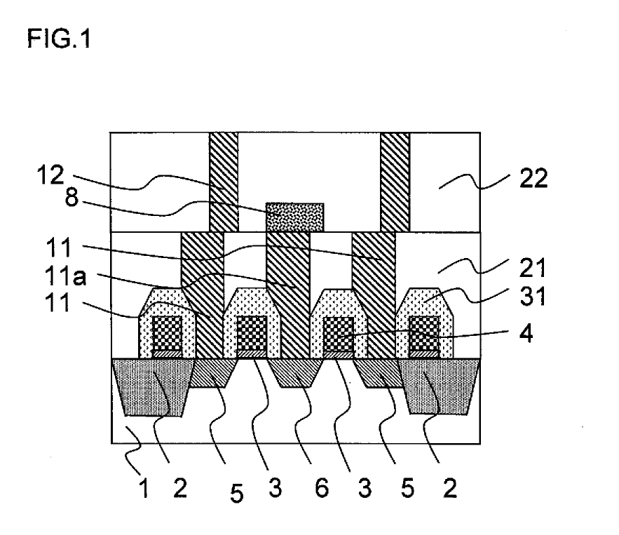

A method for manufacturing a semiconductor device according to a first exemplary embodiment will be described with reference to FIGS. 1 to 10. FIGS. 1 to 10 are longitudinal sectional views sequentially showing a method for forming a memory cell of a semiconductor device according to a first exemplary embodiment.

A principal surface of semiconductor substrate 1 was divided by isolation insulating films 2. There were formed gate oxide film 3, gate electrodes 4, diffusion layer regions 5, 6, polysilicon plugs 11, 11a, interlayer insulating film 21 (silicon oxide film), insulating film 31 (silicon nitride film) and bit line 8. After that, interlayer insulting film 22 (silicon oxide film) was formed on bit line 8.

Then, contact holes were formed in interlayer insulating film 22 and surfaces of polysilicon plugs 11 were exposed at bottom surfaces of the contact holes. A titanium film, a titanium nitride film and a tungsten film were filled in the contact holes. After that, the titanium film, the titanium nitride film and the tungsten film outside the contact holes were removed by a CMP method, to form metal plugs 12 (FIG. 1). Bit line 8 is partially and schematically shown in FIG. 1. Likewise, the bit line is partially and schematically shown in the other drawings.

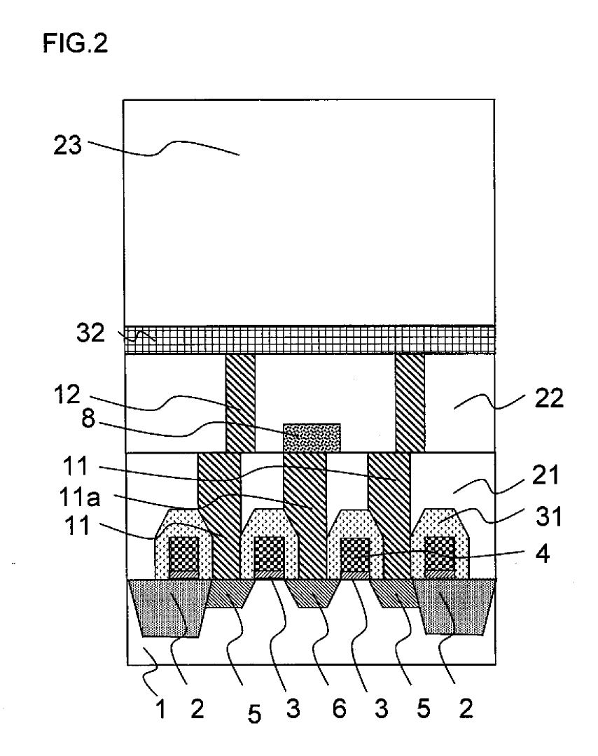

Then, a silicon nitride film as interlayer insulating film 32 and a silicon oxide film having a thickness of about 1 μm as first interlayer insulating film 23 were sequentially formed (FIG. 2).

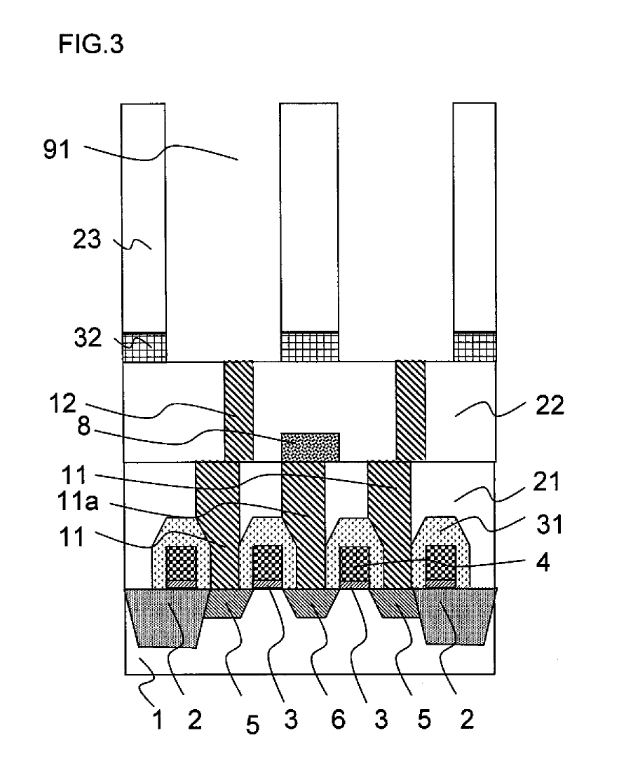

Then, first capacitor holes 91 were formed in first interlayer insulating film 23 and silicon nitride film 32 by a photolithography technique and a dry etching technique. Thereby, metal plugs 12 were exposed at bottoms of first capacitor holes 91 (FIG. 3).

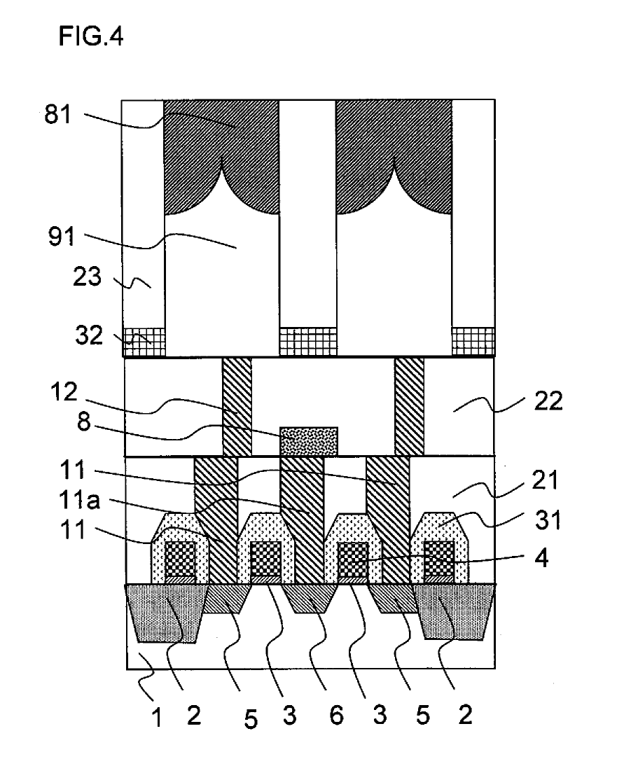

Then, carbon film 81 (corresponding to first mask material) was formed to fill parts (upper portions) of first capacitor holes 91. The carbon film was formed by using propylene (C₃H₆), helium (He) and argon (Ar) as source gases in a parallel plate type plasma CVD apparatus. After that, the carbon film outside of first capacitor holes 91 was removed by the CMP method (FIG. 4).

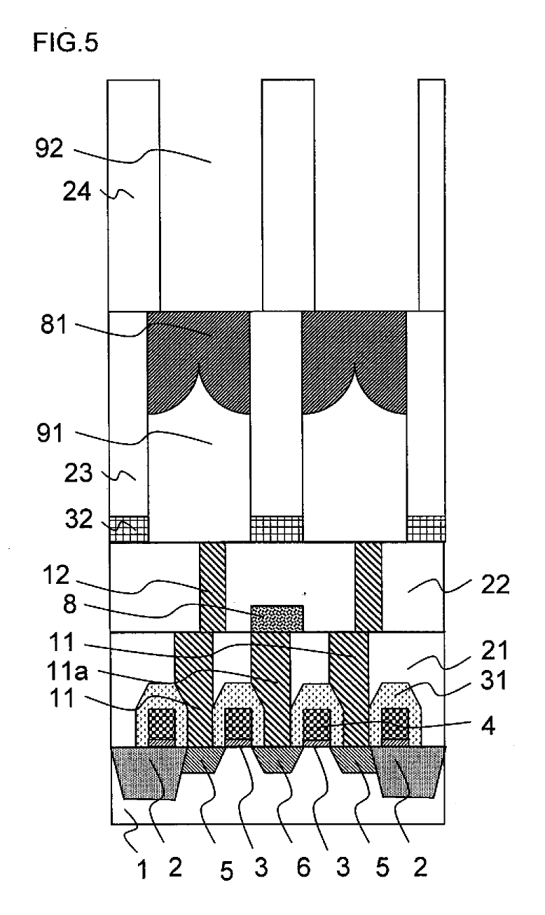

Then, a silicon oxide film having a thickness of about 1 μm was formed as second interlayer insulating film 24. Second capacitor holes 92 were formed in second interlayer insulating film 24 by the photolithography technique and the dry etching technique so that second capacitor holes were aligned with first capacitor holes 91 and carbon film 81 was exposed at bottoms of the second capacitor holes (FIG. 5). At this time, steps 40 were formed at boundary portions between first capacitor holes 91 and second capacitor holes 92.

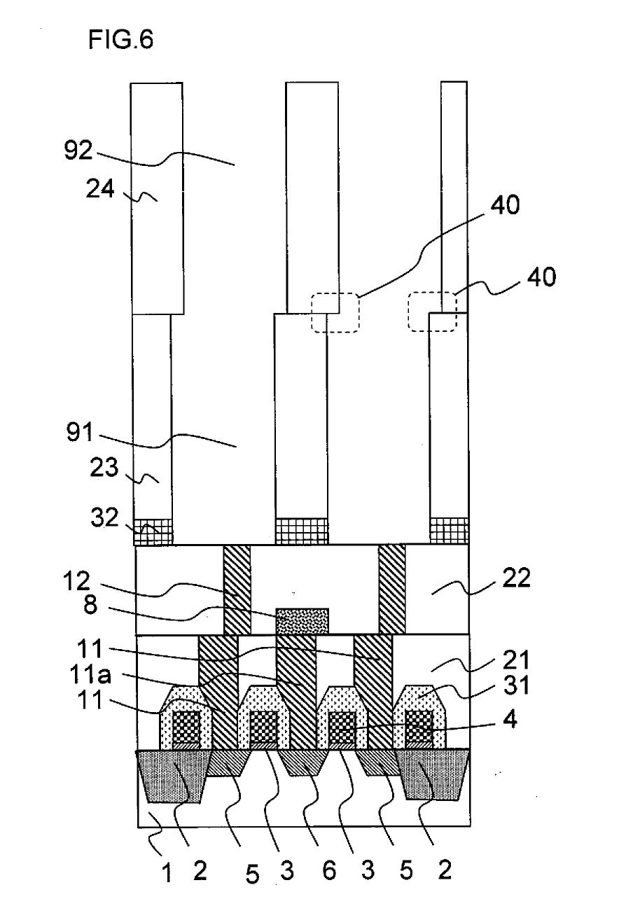

Next, carbon film 81 was removed by a plasma ashing method using oxygen (FIG. 6). Since the carbon film was filled only in the upper portions of first capacitor holes 91 and was made of carbon, the carbon film could be easily removed by the ashing. At this time, it did not occur that first and second capacitor holes 91, 92 or the upper portions of metal plugs 12 are degenerated or residues are formed on surfaces thereof.

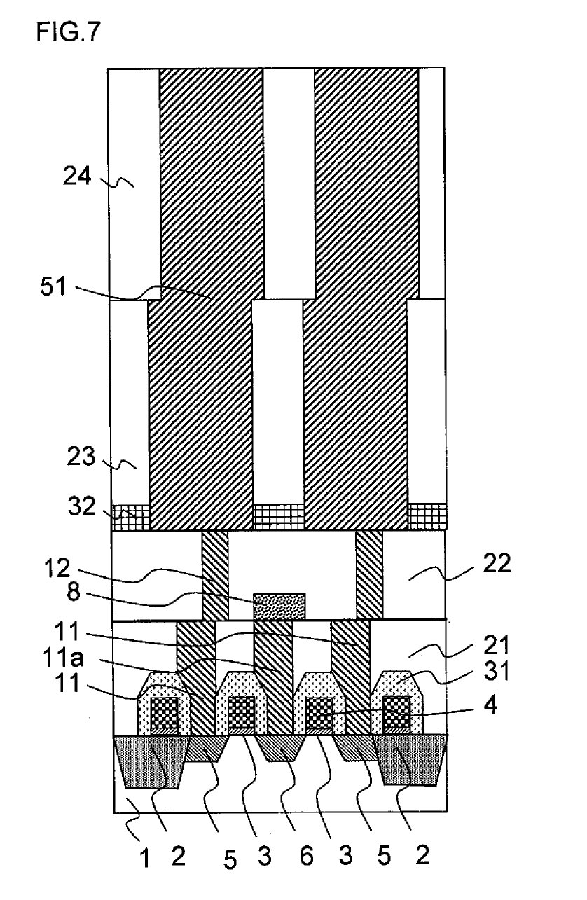

Next, first titanium nitride film 51 serving as a lower electrode was formed to fill first capacitor holes 91 and second capacitor holes 92 by a CVD method. Continuously, first titanium nitride film 51 outside second capacitor holes 92 was removed (FIG. 7).

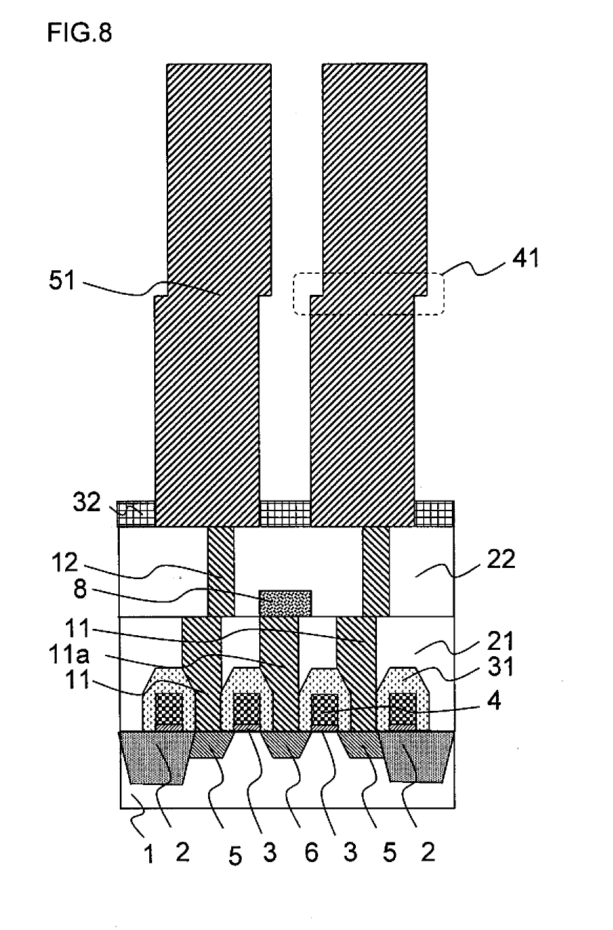

Next, first interlayer insulating film 23 and second interlayer insulating film 24 were removed by a wet etching method to obtain lower electrodes 51 having a pillar shape of two steps (FIG. 8). Lower electrodes 51 have step portions 41 at parts corresponding to boundaries between first capacitor holes 91 and second capacitor holes 92.

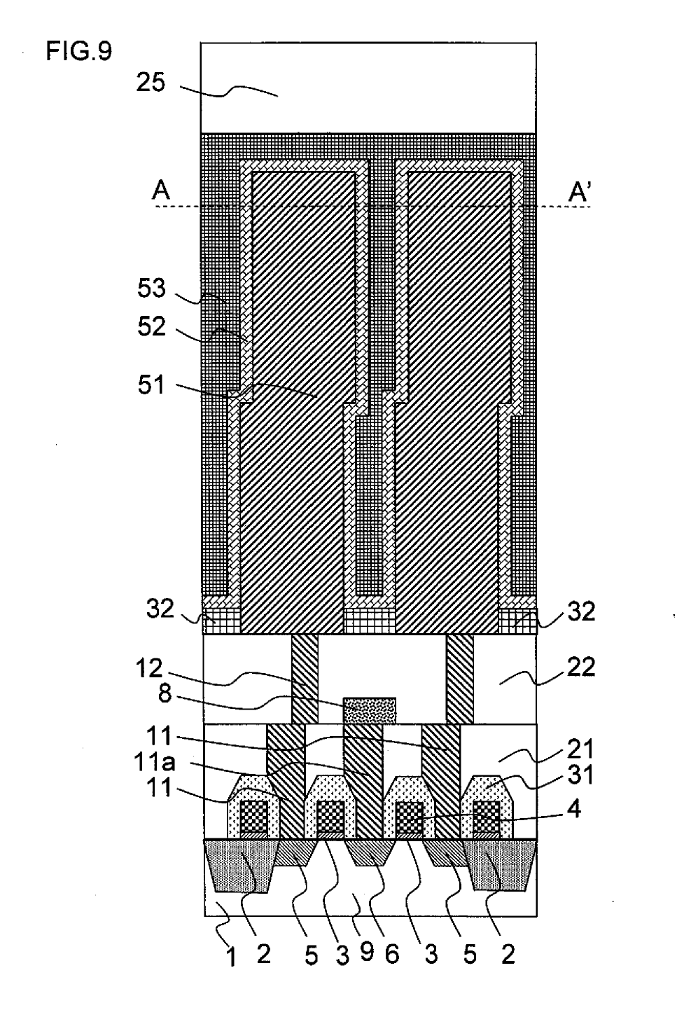

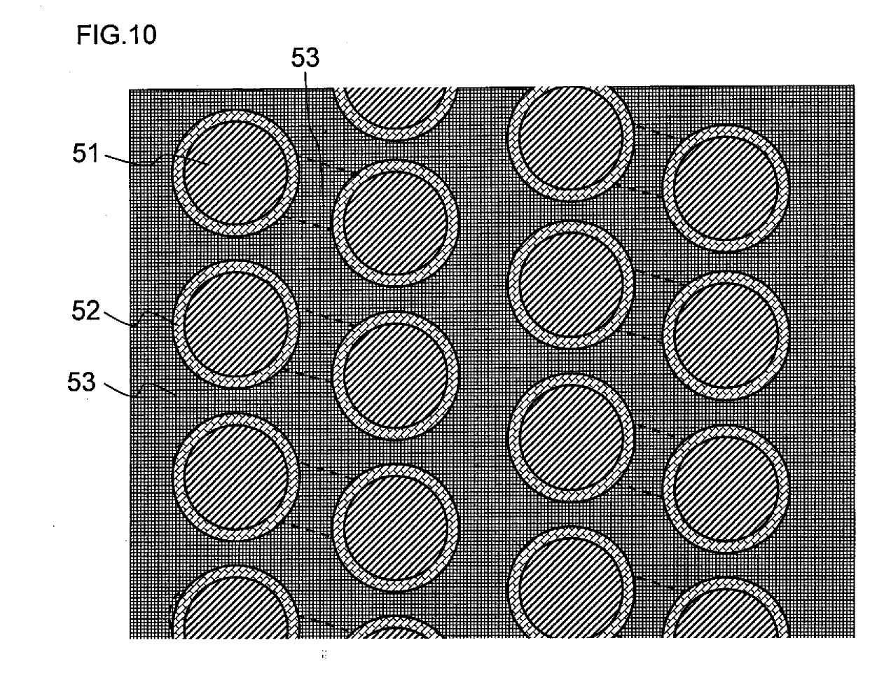

Next, stacked film 52 of an aluminum oxide film and a zirconium oxide film was formed as a capacitor dielectric film by an ALD (Atomic Layer Deposition) method. Continuously, stacked film 53 of a second titanium nitride film and a polysilicon film was formed as an upper electrode by a CVD method. Upper electrode 53 and capacitor dielectric film 52 were processed. Continuously, interlayer insulating film (silicon oxide film) 25 was formed and then necessary interlayer insulating film, connection plug, wiring and the like (which are not shown) were formed. As a result, a semiconductor device was obtained (FIG. 9). FIG. 10 is a sectional view taken along a line A-A′ of the semiconductor device shown in FIG. 9. Although only two capacitors are shown in FIG. 9, many capacitors are schematically shown in FIG. 10. In addition, dotted lines in FIG. 10 indicate active areas 9 under the capacitors.

The above semiconductor device constitutes a DRAM (Dynamic Random Access Memory) and has a plurality of memory cells. As shown in FIG. 9, each memory cell includes the MOS transistor and the capacitor that is connected to the corresponding MOS transistor via contact plugs 11, 12. In FIG. 9, source or drain area 6 is commonly provided between the two MOS transistors and two memory cells are shown.

In this exemplary embodiment, carbon film 81 is filled as the first mask material only in the upper portions of first capacitor holes 91. Due to this, carbon film 81 can be easily removed by the ashing. As a result, it is possible to secure a process margin and to thus reduce the manufacturing cost of the semiconductor device.

In addition, lower electrodes 51 can be formed by one film formation process. As a result, it is possible to stably keep the electric resistance of lower electrodes 51 low, thereby improving the reliability of the semiconductor device and increasing the yield. Additionally, it is possible to reduce the cost that is required to manufacture the semiconductor device.

By providing the capacitors including step portions 41, it is possible to increase the contact areas between capacitor dielectric film 52 and lower and upper electrodes 51, 53, thereby increasing the capacitor capacity.

### Second Exemplary Embodiment

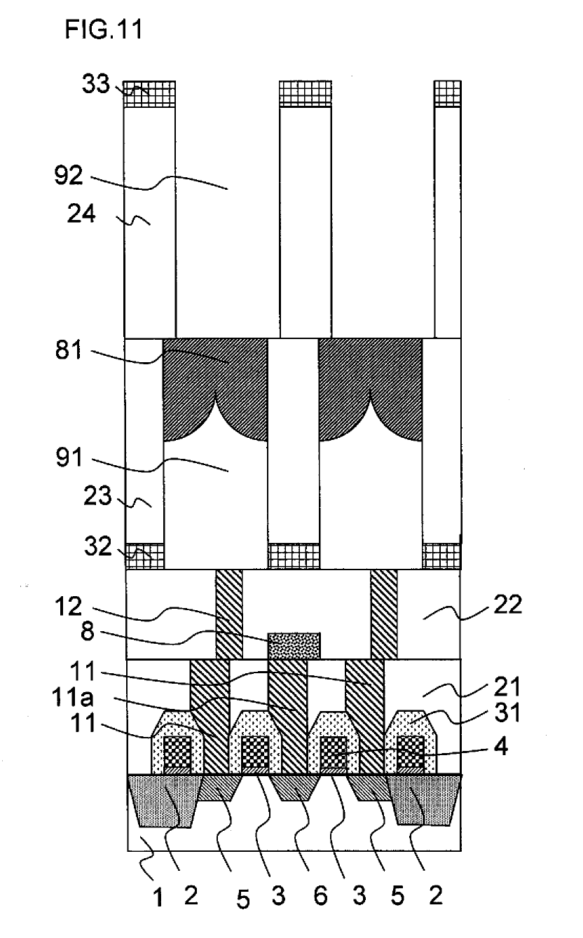

In the followings, a method for manufacturing a semiconductor device according to a second exemplary embodiment will be described with reference to FIGS. 11 to 20. FIGS. 11 to 20 are longitudinal sectional views sequentially showing a method for forming a memory cell of a semiconductor device. This exemplary embodiment is different from the first exemplary embodiment, in that beam 33 made of a silicon nitride film is provided between lower electrodes of a plurality of capacitors so as to prevent the lower electrodes from being modified or falling down.

There were formed first gate oxide film 3, gate electrodes 4, diffusion layer regions 5, 6, polysilicon plugs 11, 11a, interlayer insulating films (silicon oxide films) 21, 22, 32, insulating film (silicon nitride film) 31, polysilicon plugs 11, metal plugs 12, first interlayer insulating film 23, first capacitor holes 91 and carbon film 81 on silicon substrate 1 by the method the same as the first exemplary embodiment (FIG. 4).

Next, there were formed a silicon oxide film having a thickness of 1 μm serving as second interlayer insulating film 24 and silicon nitride film 33 (corresponding to a third insulating film). By the photolithography technique and the dry etching technique, second capacitor holes 92 were formed in second interlayer insulating film 24 and silicon nitride film 33 so that the second capacitor holes were aligned with first capacitor holes 91, thereby exposing carbon film 81 at bottoms of the second capacitor holes (FIG. 11).

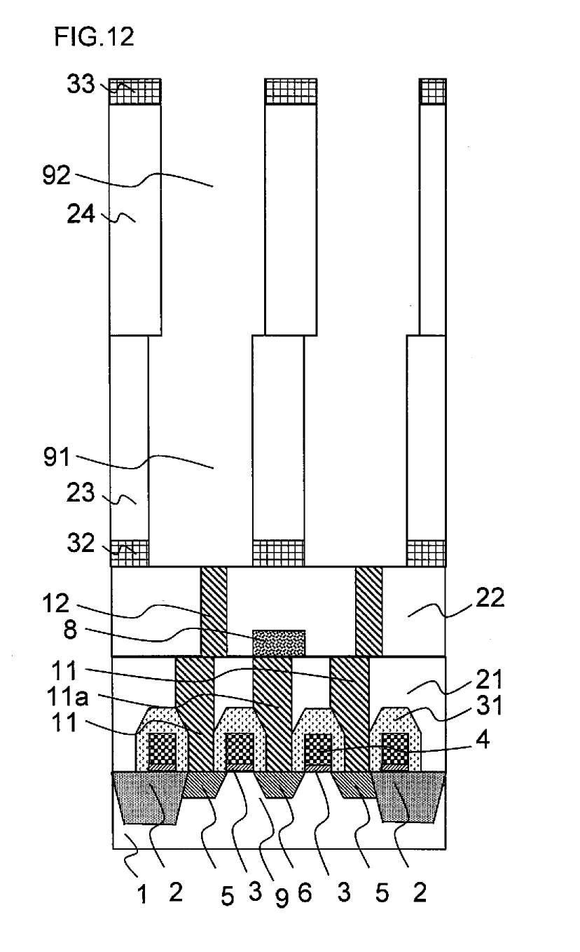

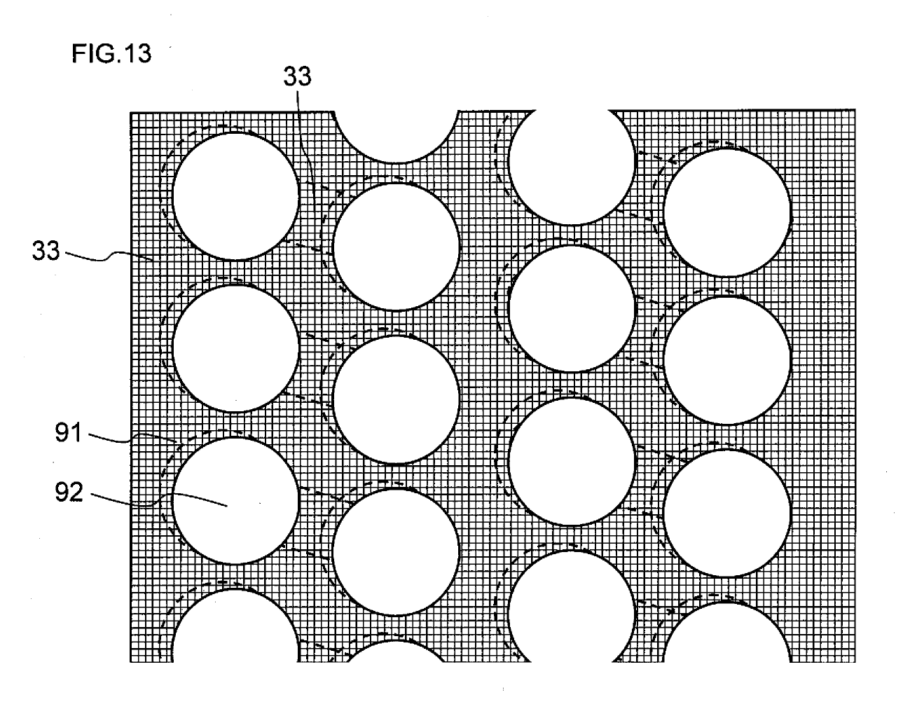

Continuously, carbon film 81 was removed by the plasma ashing method using oxygen (FIG. 12). FIG. 13 is a plan view of the semiconductor device shown in FIG. 12. The dotted lines of FIG. 13 indicate bottom surfaces of first capacitor holes 91 and active areas 9.

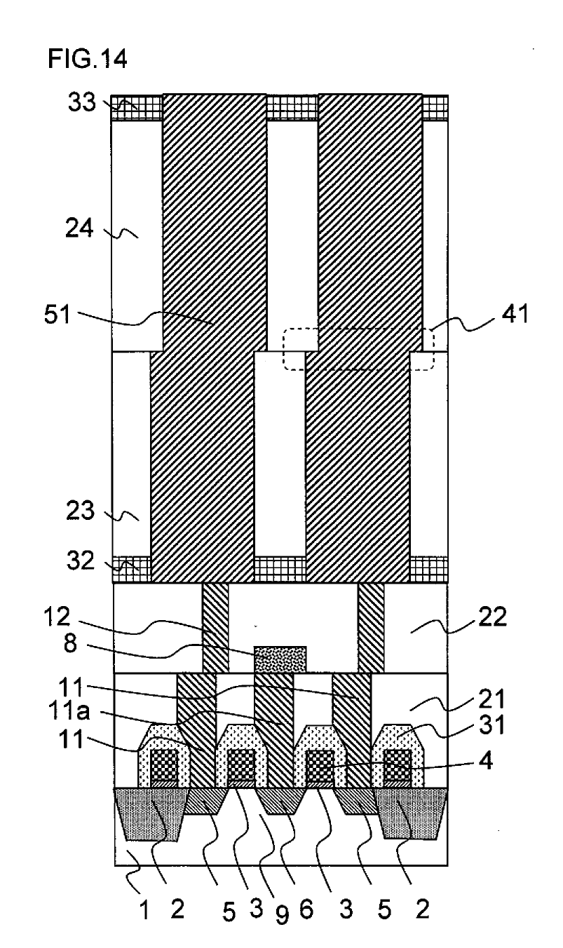

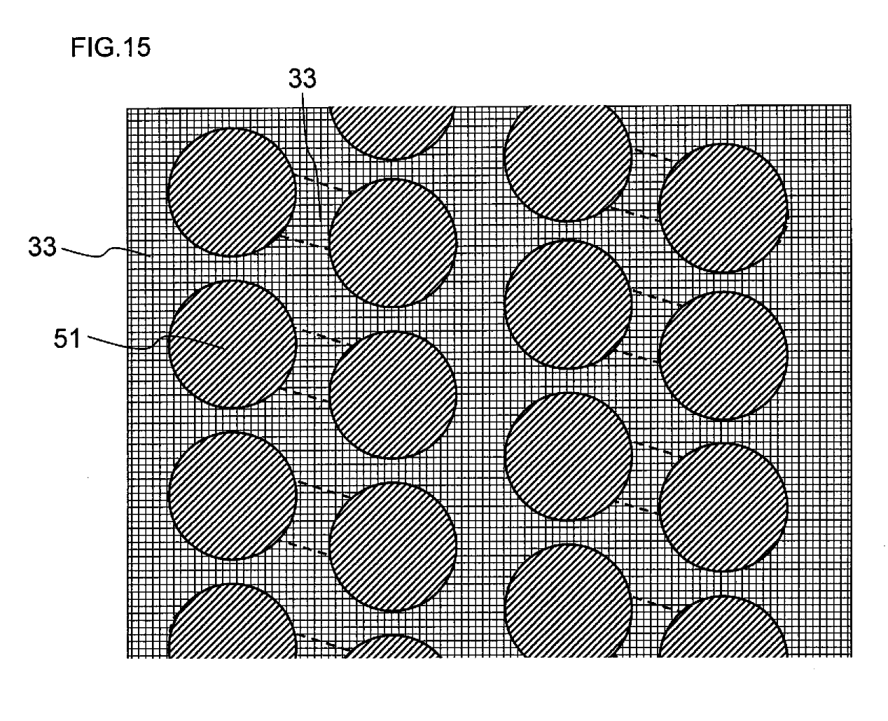

Next, first titanium nitride film 51 serving as a lower electrode was formed to fill first capacitor holes 91 and second capacitor holes 92 by the CVD method. Continuously, first titanium nitride film 51 outside second capacitor holes 92 was removed to obtain lower electrodes 51 including pillars of two steps connected (FIG. 14). FIG. 15 is a plan view of the semiconductor device shown in FIG. 14. As shown in FIG. 14, lower electrodes 51 include step portions 41.

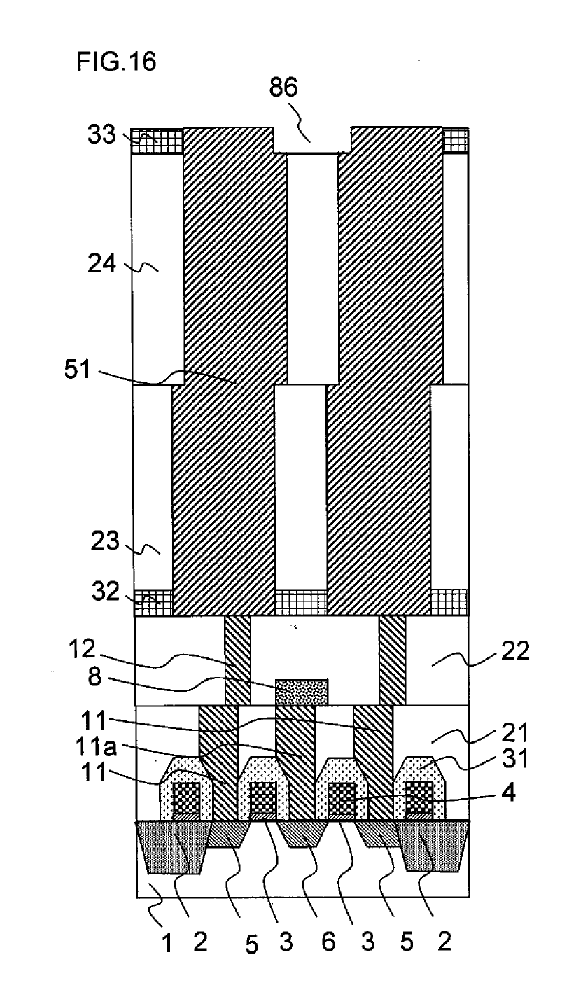

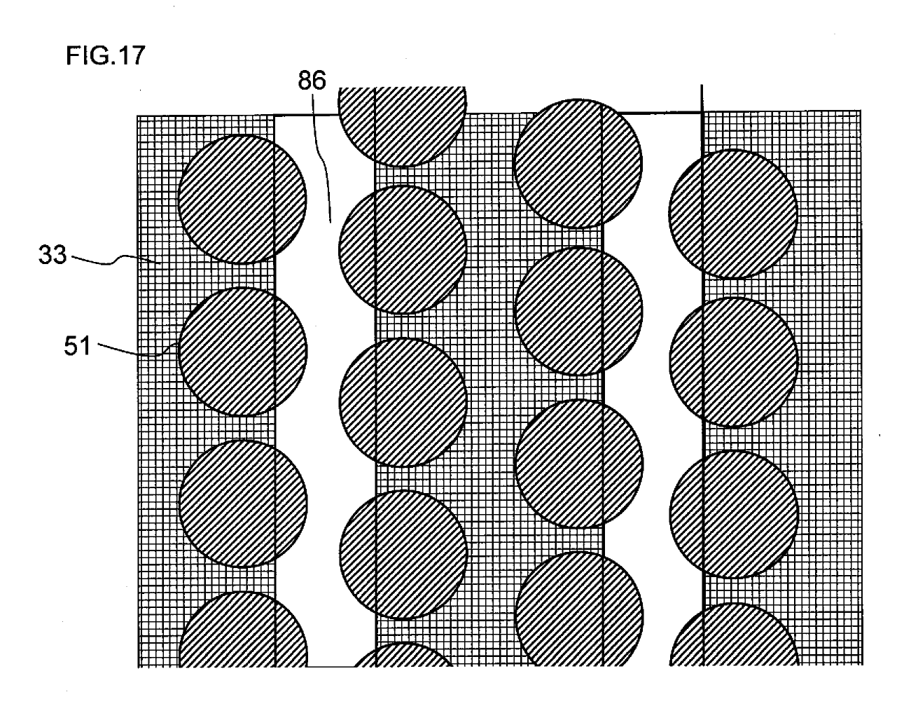

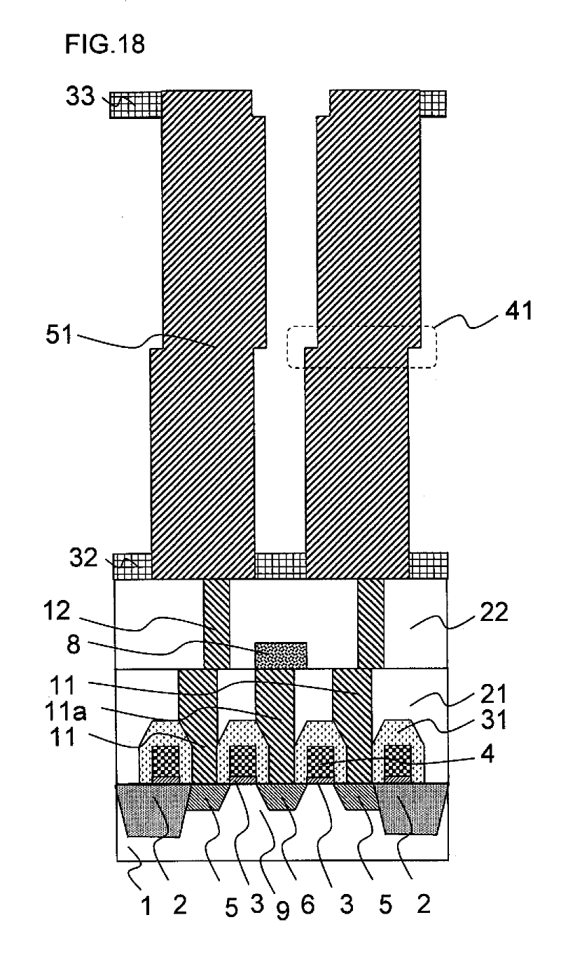

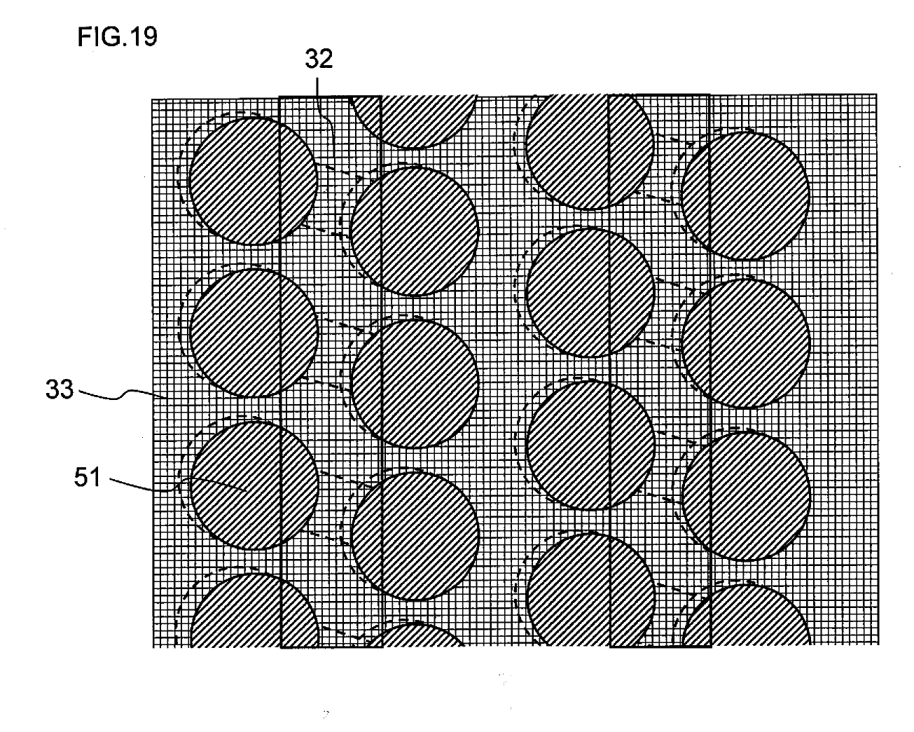

Next, parts of silicon nitride film 33 were removed by the photolithography technique and the dry etching technique to form windows 86 (FIG. 16). FIG. 17 is a plan view of the semiconductor device shown in FIG. 16. First interlayer insulating film 23 and second interlayer insulating film 24 were removed by the wet etching method using hydrofluoric acid (HF), so that lower electrodes 51 having a two-stage pillar shape were obtained (FIG. 18). FIG. 19 is a plan view of the semiconductor device shown in FIG. 18. The dotted lines of FIG. 19 indicate bottom surfaces of lower electrodes 51 and active areas 9. At this time, since the etchant (HF) invaded even the lower portions of silicon nitride film 33 through windows 86 formed in silicon nitride film 33, all of first interlayer insulating film 23 and second interlayer insulating film 24 were removed. In addition, at this time, as shown in FIG. 19, since silicon nitride film 33 was provided between neighboring lower electrodes 51, the silicon nitride film served as a beam supporting lower electrodes 51 so that the lower electrodes did not contact each other or fall down.

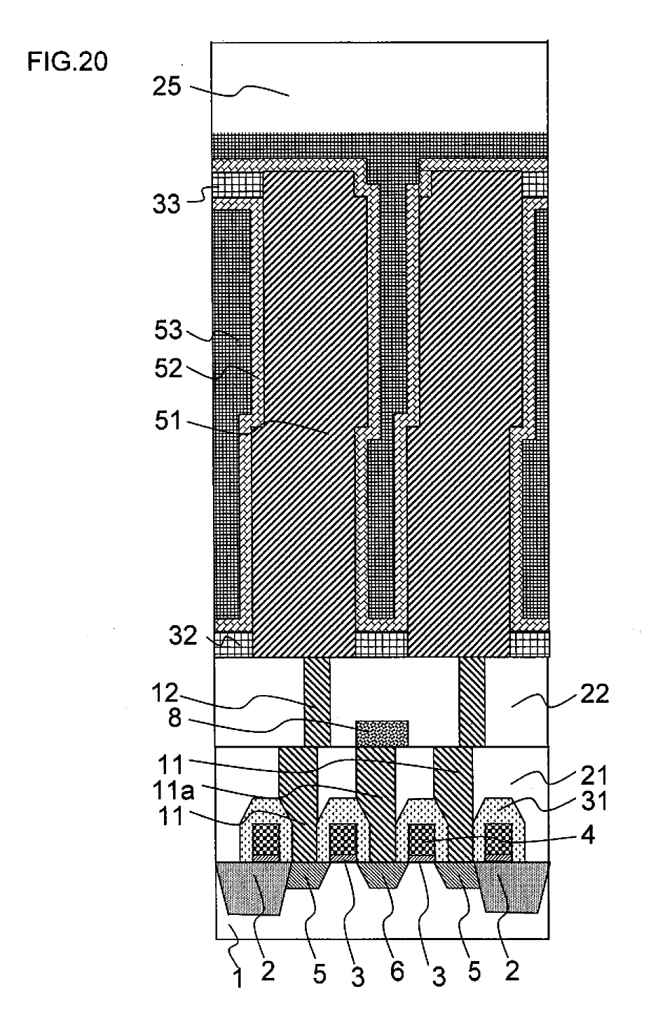

Next, like the first exemplary embodiment, capacitor dielectric film 52, upper electrode 53, an interlayer insulating film, a connection plug, a wiring and the like (which are not shown) were formed to obtain a semiconductor device (FIG. 20).

As described in this exemplary embodiment, the invention can be applied to a capacitor including a beam. In this exemplary embodiment, as shown in FIGS. 18 and 19, beam made of silicon nitride film 33 is provided between the lower electrodes of the capacitors. Due to this, when removing interlayer insulating films 23, 24 to expose lower electrodes 51, it is possible to effectively prevent the capacitors from falling down. As a result, it is possible to increase the yield of the semiconductor device and to thus reduce the manufacturing cost of the semiconductor device.

### Third Exemplary Embodiment

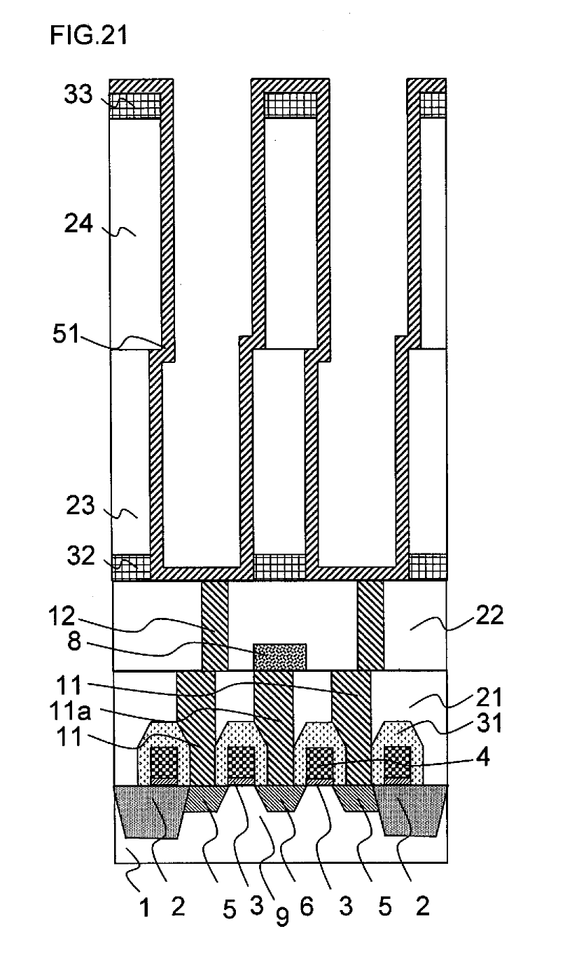

In the followings, a method for manufacturing a semiconductor device according to a third exemplary embodiment will be described with reference to FIGS. 21 to 31. FIGS. 21 to 31 are longitudinal sectional views sequentially showing a method for forming a memory cell of a semiconductor device. This exemplary embodiment is different from the second exemplary embodiment, in that crown-type capacitors are formed in which both sides of the lower electrodes serve as electrodes so as to increase charge accumulation capacities of the capacitors.

First, there were formed gate oxide film 3, gate electrodes 4, diffusion layer regions 5, 6, polysilicon plugs 11, 11a, interlayer insulating films (silicon oxide films) 21, 22, 32, insulating film (silicon nitride film) 31, polysilicon plugs 11, metal plugs 12, first interlayer insulating film 23, first capacitor holes 91 and second capacitor holes 92 on silicon substrate 1 by the method the same as the first and second exemplary embodiments (FIG. 12).

Then, first titanium nitride film 51 having a thickness of about 10 nm serves as the lower electrodes was formed along side surfaces of first capacitor holes 91 and second capacitor hole 92 by the CVD method (FIG. 21).

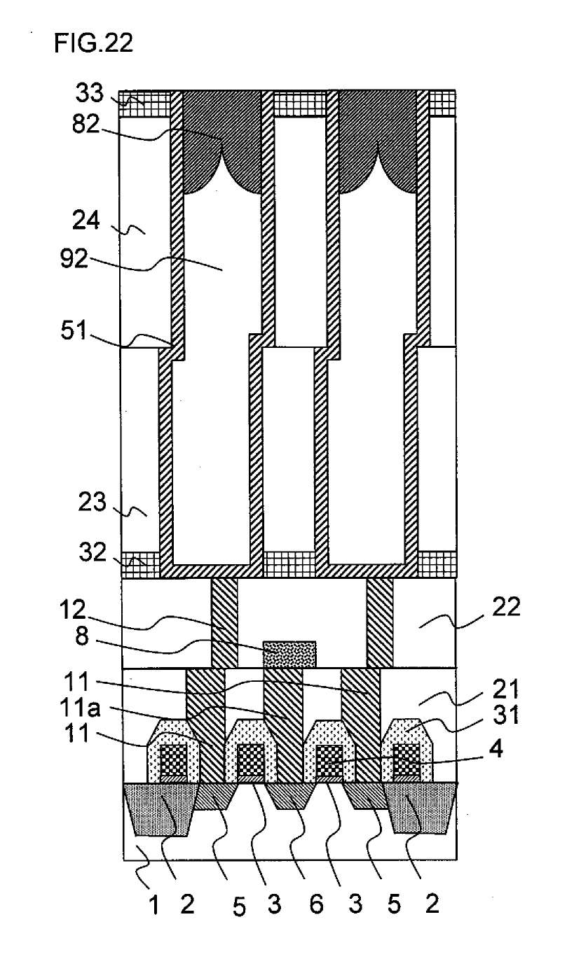

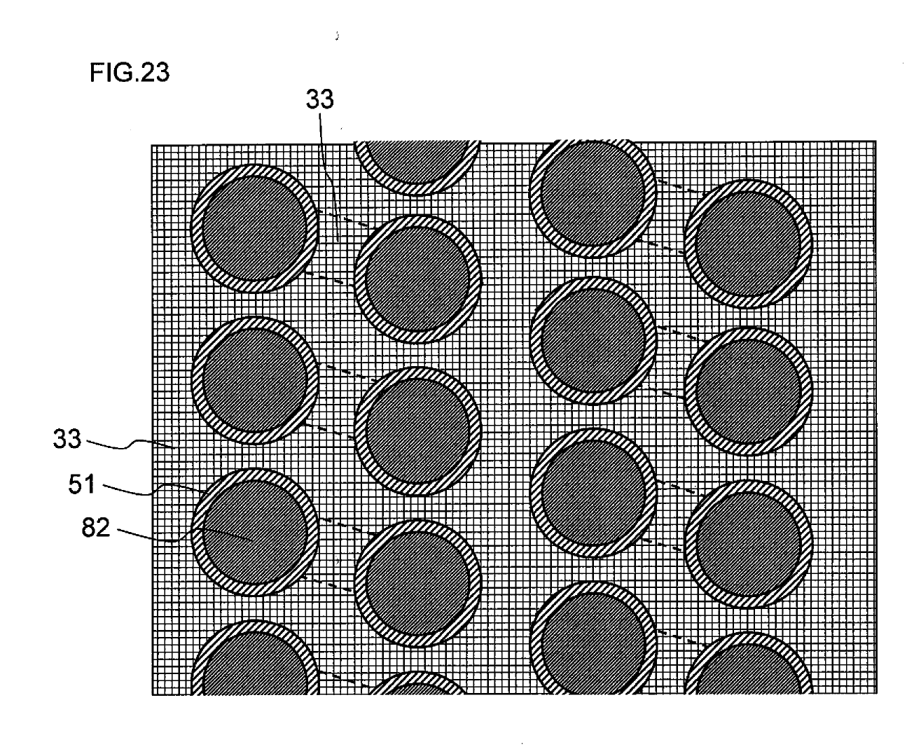

Next, carbon film 82 (corresponding to second mask material) was formed to fill the inside of first titanium nitride film 51, which were parts (upper portions) of second capacitor holes 92. Continuously, carbon film 82 outside second capacitor holes 92 and first titanium nitride film 51 outside second capacitor holes 92 were removed by the CMP method (FIG. 22). At this time, lower electrodes 51 having a recess shape were formed along inner walls of first capacitor holes 91 and second capacitor holes 92. FIG. 23 is a plan view of the semiconductor device shown in FIG. 22. The dotted lines of FIG. 23 indicate active areas 9.

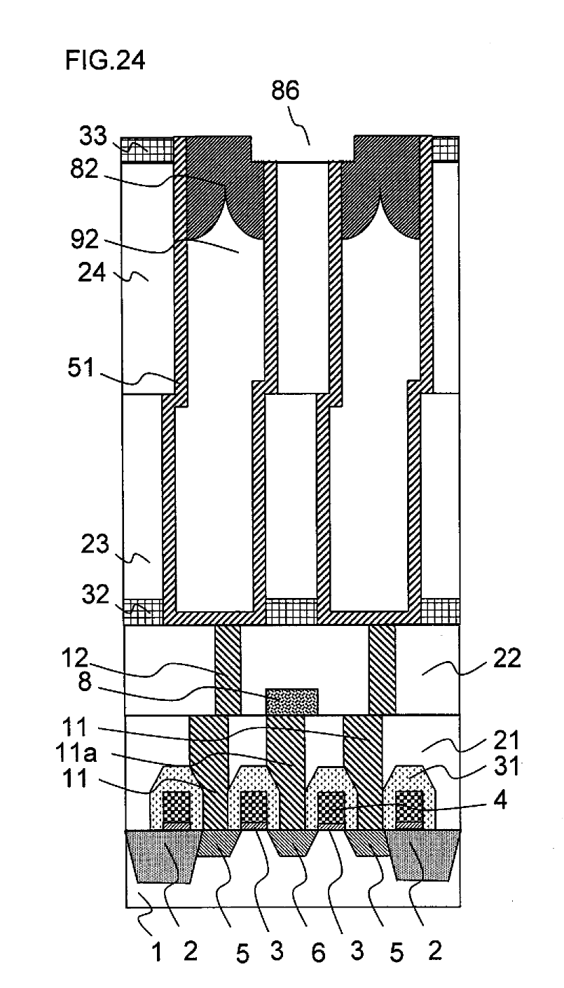

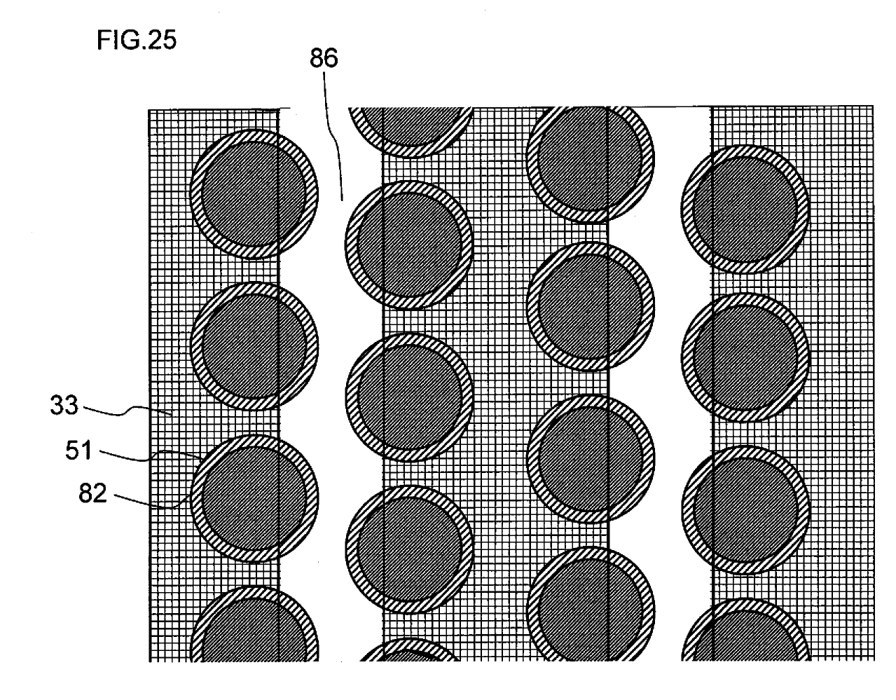

Next, parts of silicon nitride film 33 (corresponding to a third insulating film) were removed by the photolithography technique and the dry etching technique to form windows 86 (FIG. 24). FIG. 25 is a plan view of the semiconductor device shown in FIG. 24.

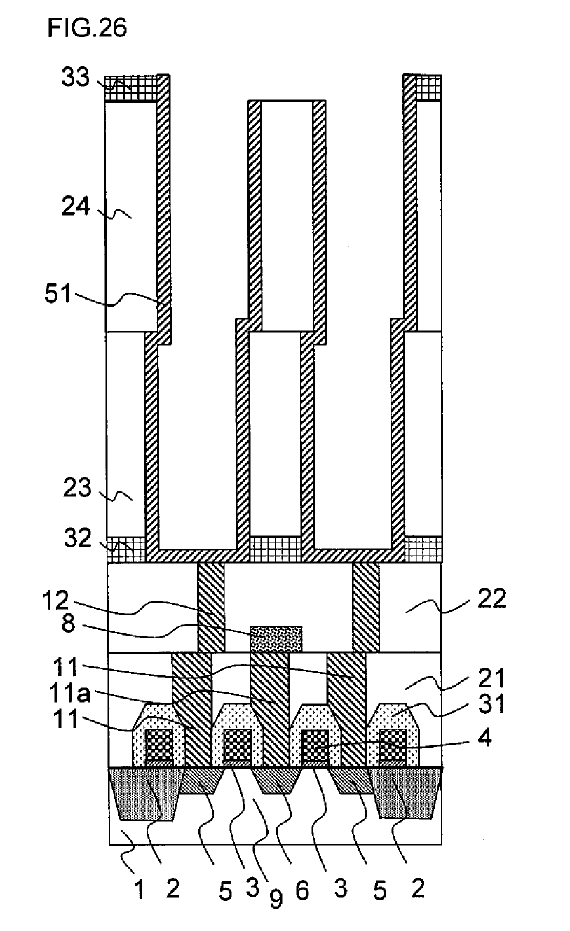

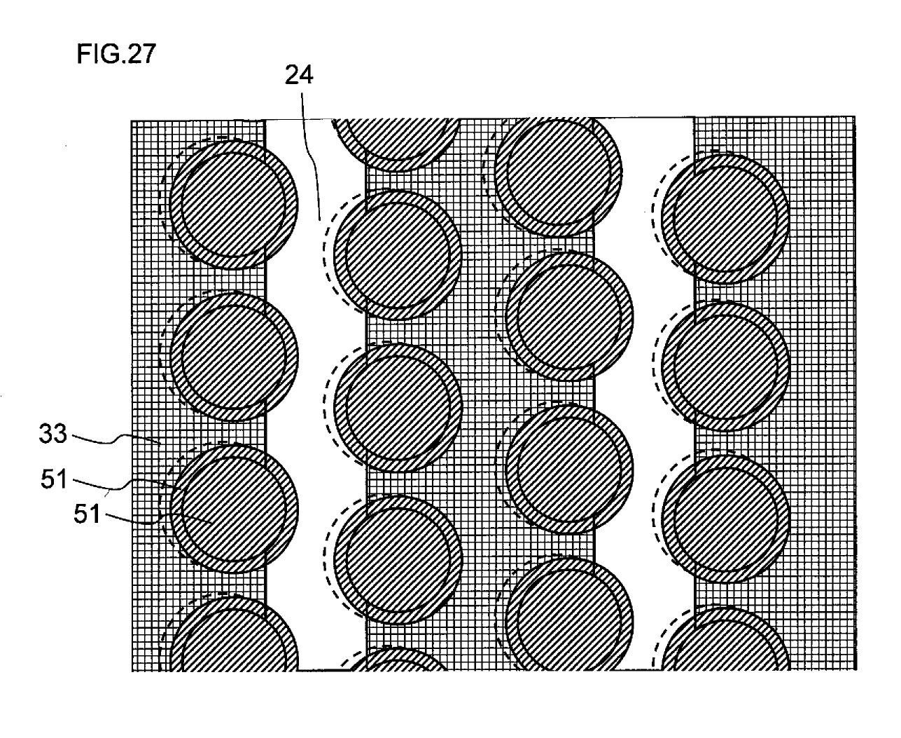

Next, carbon film 82 was removed by the plasma ashing method using oxygen (FIG. 26). FIG. 27 is a plan view of the semiconductor device shown in FIG. 26. The dotted lines of FIG. 27 indicate bottom surfaces of first capacitor holes 91. Since carbon film 82 was filled only in the upper portions of second capacitor holes 92 and made of carbon, the carbon film could be easily removed by the ashing. At this time, it did not occur that lower electrodes 51 are degenerated or residues are formed on surfaces thereof.

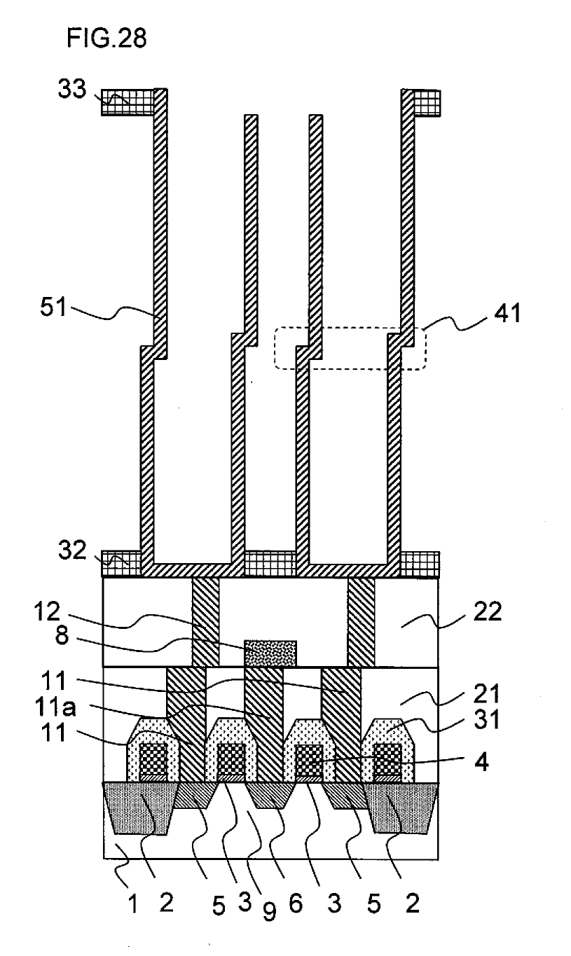

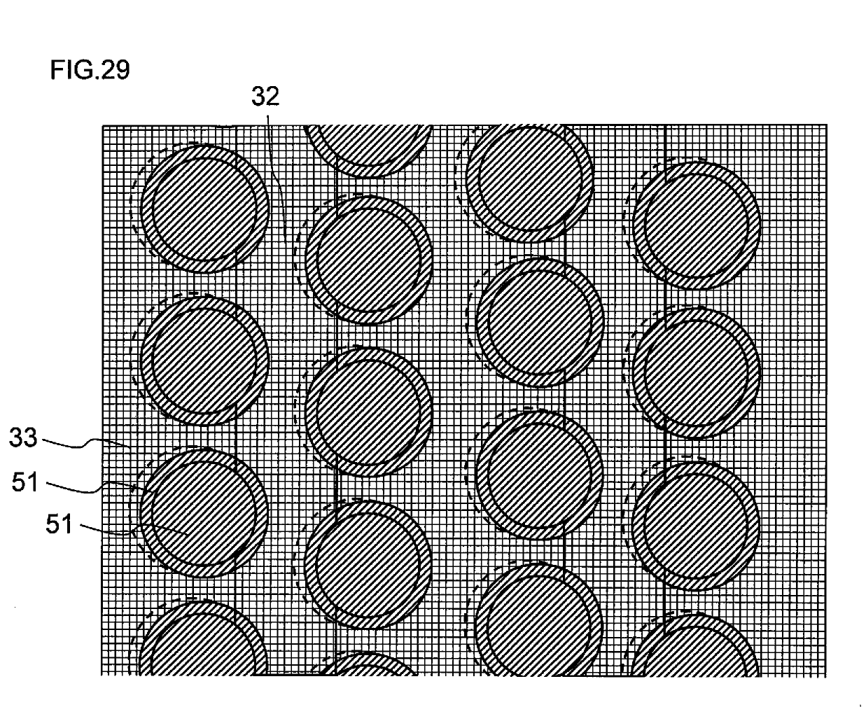

Continuously, first interlayer insulating film 23 and second interlayer insulating film 24 were removed by the wet etching method using hydrofluoric acid (HF) as etchant, so that lower electrodes 51 having a two-stage recess shape were obtained (FIG. 28). FIG. 29 is a plan view of the semiconductor device shown in FIG. 28. As shown in FIG. 28, lower electrodes 51 include step portions 41.

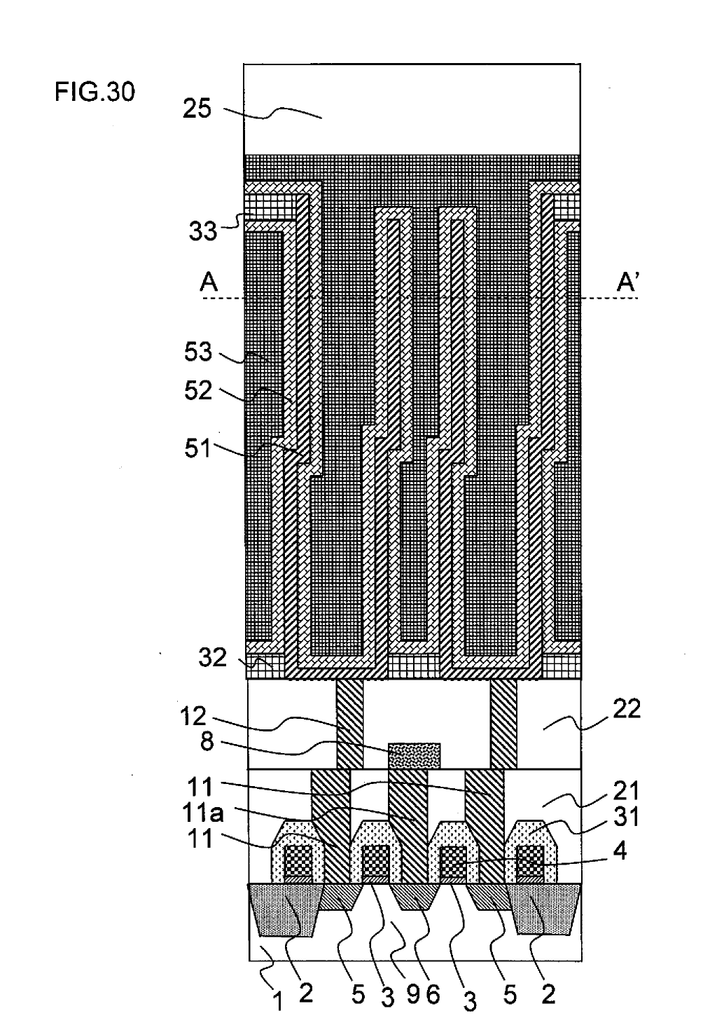

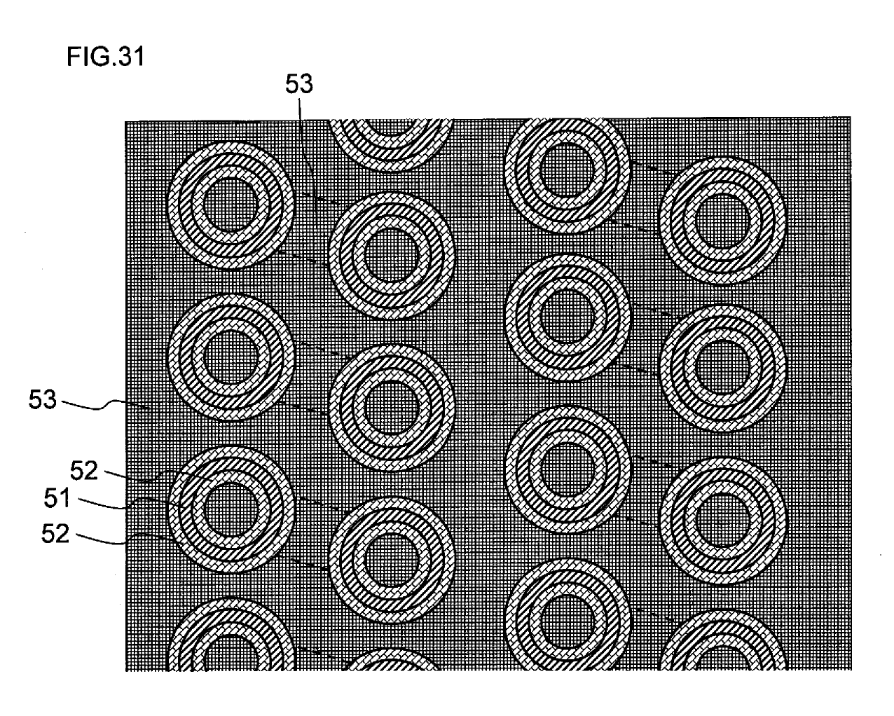

Next, like the first exemplary embodiment, capacitor dielectric film 52, upper electrode 53, an interlayer insulating film, a connection plug, a wiring and the like (which are not shown) were formed to obtain a semiconductor device (FIG. 30). FIG. 31 is a sectional view taken along a line A-A′ of the semiconductor device shown in FIG. 30. The dotted lines of FIG. 31 indicate active areas 9. Like this exemplary embodiment, the invention can be applied to a crown-type capacitor in which both sides of the lower electrodes serve as electrodes.

In this exemplary embodiment, it is possible to form a capacitor having a crown structure in which the capacitor dielectric film and the upper electrode are formed on inner and outer surfaces of lower electrodes 51 having a recess shape. As a result, it is possible to increase the contact areas between capacitor dielectric film 52 and lower and upper electrodes 51, 53, thereby increasing the capacitor capacity. Additionally, in a capacitor having a crown structure, lower electrodes 51 are generally apt to fall down when forming lower electrodes 51. However, in this exemplary embodiment, as shown in FIGS. 29 and 30, beam made of silicon nitride film 33 has been provided to parts except between the two capacitors. Due to this, it is possible to effectively prevent lower electrodes 51 from falling down. As a result, it is possible to improve the yield of the semiconductor device and to thus reduce the manufacturing cost of the semiconductor device.

It is apparent that the present invention is not limited to the above embodiments, but may be modified and changed without departing from the scope and spirit of the invention.

1. A method for manufacturing a semiconductor device including a capacitor, the method comprising:
forming a first interlayer insulating film;
forming a first capacitor hole in the first interlayer insulating film;
filling a first mask material in an upper portion of the first capacitor hole;
forming a second interlayer insulating film on the first interlayer insulating film;
forming a second capacitor hole in the second interlayer insulating film so that the second capacitor hole is aligned with the first capacitor hole, the second capacitor hole being formed until the first mask material is exposed;
removing the first mask material;
forming a lower electrode in the first and second capacitor holes;
removing the first and second interlayer insulating films; and
sequentially forming a capacitor dielectric film and an upper electrode on an exposed surface of the lower electrode.

2. The method for manufacturing a semiconductor device according to claim 1,
wherein the first mask material is carbon, and
wherein in removing the first mask material, the first mask material is removed by an ashing.

3. The method for manufacturing a semiconductor device according to claim 1,
wherein in forming the second capacitor hole, the second capacitor hole is formed so that a step is formed at a boundary between the first capacitor hole and the second capacitor hole.

4. The method for manufacturing a semiconductor device according to claim 1,
wherein in forming the lower electrode, the lower electrode having a pillar shape is formed so that the lower electrode is filled in the first and second capacitor holes.

5. The method for manufacturing a semiconductor device according to claim 4, further comprising:
forming a third insulating film on the second interlayer insulating film, between forming the second interlayer insulating film and forming the second capacitor hole; and
partially removing the third insulating film so that the continuous third insulating film remains in contact with outer side surfaces of a plurality of the lower electrodes, to form a beam made of the third insulating film, between forming the lower electrode and removing the first and second interlayer insulating films,
wherein in forming the first capacitor hole, a plurality of the first capacitor holes are formed,
in forming the second capacitor hole, a plurality of the second capacitor holes are formed in the third insulating film and the second interlayer insulating film,
in forming the lower electrode, a plurality of the lower electrodes are formed, and
in removing the first and second interlayer insulating films, the first and second interlayer insulating films are removed by etching using the remaining third insulating film as a mask.

6. The method for manufacturing a semiconductor device according to claim 1,
wherein in forming the lower electrode, the lower electrode having a recess shape is formed on inner walls of the first and second capacitor holes.

7. The method for manufacturing a semiconductor device according to claim 6, further comprising:
forming a third insulating film on the second interlayer insulating film, between forming the second interlayer insulating film and forming the second capacitor hole;
filling a second mask material in an upper portion of the second capacitor hole, between forming the lower electrode and removing the first and second interlayer insulating films;
partially removing the third insulating film so that the continuous third insulating film remains in contact with outer side surfaces of a plurality of the lower electrodes, to form a beam made of the third insulating film, after filling the second mask material; and
removing the second mask material, after partially removing the third insulating film,
wherein in forming the first capacitor hole, a plurality of the first capacitor holes are formed,
in forming the second capacitor hole, a plurality of the second capacitor holes are formed in the third insulating film and the second interlayer insulating film,
in forming the lower electrode, a plurality of the lower electrodes are formed, and
in removing the first and second interlayer insulating films, the first and second interlayer insulating films are removed by etching using the remaining third insulating film as a mask.

8. The method for manufacturing a semiconductor device according to claim 1, before forming the first interlayer insulating film, further comprising:
forming a transistor including source and drain regions;
forming a bit line so that the bit line is connected to one of the source and drain regions; and
forming a contact plug so that the contact plug is connected to the other of the source and drain regions,
wherein in forming the first capacitor hole, the first capacitor hole is formed at a position corresponding to the contact plug.

9. A method for manufacturing a semiconductor device including a capacitor, the method comprising:
forming a first interlayer insulating film;
forming a first capacitor hole in the first interlayer insulating film;
filling a first mask material in an upper portion of the first capacitor hole;
forming a second interlayer insulating film on the first interlayer insulating film;
forming a second capacitor hole in the second interlayer insulating film so that the second capacitor hole is aligned with the first capacitor hole, the second capacitor hole being formed until the first mask material is exposed;
removing the first mask material;
forming a lower electrode having a pillar shape so that the lower electrode is filled in the first and second capacitor holes;
removing the first and second interlayer insulating films; and
sequentially forming a capacitor dielectric film and an upper electrode on an exposed surface of the lower electrode having the pillar shape.

10. The method for manufacturing a semiconductor device according to claim 9,
wherein the first mask material is carbon, and
wherein in removing the first mask material, the first mask material is removed by an ashing.

11. The method for manufacturing a semiconductor device according to claim 9,
wherein in forming the second capacitor hole, the second capacitor hole is formed so that a step is formed at a boundary between the first capacitor hole and the second capacitor hole.

12. The method for manufacturing a semiconductor device according to claim 9, further comprising:
forming a third insulating film on the second interlayer insulating film, between forming the second interlayer insulating film and forming the second capacitor hole; and
partially removing the third insulating film so that the continuous third insulating film remains in contact with outer side surfaces of a plurality of the lower electrodes, to form a beam made of the third insulating film, between forming the lower electrode and removing the first and second interlayer insulating films,
wherein in forming the first capacitor hole, a plurality of the first capacitor holes are formed,
in forming the second capacitor hole, a plurality of the second capacitor holes are formed in the third insulating film and the second interlayer insulating film,
in forming the lower electrode, a plurality of the lower electrodes are formed, and
in removing the first and second interlayer insulating films, the first and second interlayer insulating films are removed by etching using the remaining third insulating film as a mask.

13. The method for manufacturing a semiconductor device according to claim 9, before forming the first interlayer insulating film, further comprising:
forming a transistor including source and drain regions;
forming a bit line so that the bit line is connected to one of the source and drain regions; and
forming a contact plug so that the contact plug is connected to the other of the source and drain regions,
wherein in forming the first capacitor hole, the first capacitor hole is formed at a position corresponding to the contact plug.

14. A method for manufacturing a semiconductor device including a capacitor, the method comprising:
forming a first interlayer insulating film;
forming a first capacitor hole in the first interlayer insulating film;
filling a first mask material in an upper portion of the first capacitor hole;
forming a second interlayer insulating film on the first interlayer insulating film;
forming a second capacitor hole in the second interlayer insulating film so that the second capacitor hole is aligned with the first capacitor hole, the second capacitor hole being formed until the first mask material is exposed;
removing the first mask material;
forming a lower electrode having a recess shape on inner walls of the first and second capacitor holes;
removing the first and second interlayer insulating films; and
sequentially forming a capacitor dielectric film and an upper electrode on an exposed surface of the lower electrode.

15. The method for manufacturing a semiconductor device according to claim 14,
wherein the first mask material is carbon, and
wherein in removing the first mask material, the first mask material is removed by an ashing.

16. The method for manufacturing a semiconductor device according to claim 14,
wherein in forming the second capacitor hole, the second capacitor hole is formed so that a step is formed at a boundary between the first capacitor hole and the second capacitor hole.

17. The method for manufacturing a semiconductor device according to claim 14, further comprising:
forming a third insulating film on the second interlayer insulating film, between forming the second interlayer insulating film and forming the second capacitor hole;
filling a second mask material in an upper portion of the second capacitor hole, between forming the lower electrode and removing the first and second interlayer insulating films;
partially removing the third insulating film so that the continuous third insulating film remains in contact with outer side surfaces of a plurality of the lower electrodes, to form a beam made of the third insulating film, after filling the second mask material; and
removing the second mask material, after partially removing the third insulating film,
wherein in forming the first capacitor hole, a plurality of the first capacitor holes are formed,
in forming the second capacitor hole, a plurality of the second capacitor holes are formed in the third insulating film and the second interlayer insulating film,
in forming the lower electrode, a plurality of the lower electrodes are formed, and
in removing the first and second interlayer insulating films, the first and second interlayer insulating films are removed by etching using the remaining third insulating film as a mask.

18. The method for manufacturing a semiconductor device according to claim 14, before forming the first interlayer insulating film, further comprising:
forming a transistor including source and drain regions;
forming a bit line so that the bit line is connected to one of the source and drain regions; and
forming a contact plug so that the contact plug is connected to the other of the source and drain regions,
wherein in forming the first capacitor hole, the first capacitor hole is formed at a position corresponding to the contact plug.
